(19) United States
(12) Patent Application Publication
(10) Pub. No.: US 2024/0339297 A1
(43) Pub. Date: Oct. 10, 2024

(54) PLASMA PROCESSING SYSTEMS WITH MATCHING NETWORK AND METHODS

(71) Applicant: Tokyo Electron Limited, Tokyo (JP)

(72) Inventors: Qiang Wang, Austin, TX (US); Peter Lowell George Ventzek, Austin, TX (US); Shyam Sridhar, Austin, TX (US); Mitsunori Ohata, Taiwa-cho (JP)

(21) Appl. No.: 18/296,944

(22) Filed: Apr. 6, 2023

(51) Int. Cl. H01J 37/32; H03H 7/38

(52) U.S. Cl. CPC H01J 37/32183; H01J 37/32091; H01J 37/3211; H03H 7/38; H01J 37/32155; H01J 2237/24564; H01J 2237/334

(57) ABSTRACT

An embodiment matching circuit for a plasma tool includes an impedance matching network configured to be coupled between a power supply and an antenna of a plasma chamber. The power supply is configured to provide power to and excite the antenna at a first frequency to generate a plasma. The impedance matching network is configured such that, during operation of the plasma chamber at the first frequency, a phase angle between a voltage and a current in the impedance matching network is matched to be 0°, and an impedance of the impedance matching network and the plasma chamber equals an impedance of the power supply. The impedance matching network includes a first adjustable reactive component; and a first fixed-length transmission line coupled between the first adjustable reactive component and an input of the antenna.

### TECHNICAL FIELD

The present invention relates generally to plasma processing, and, in particular embodiments, to plasma processing systems with matching network and methods.

### BACKGROUND

Semiconductor fabrication processes may involve various manufacturing techniques including formation, patterning and removing a number of layers over a substrate. Plasma processes are commonly used in various steps of semiconductor fabrication processes. For example, reactive ion etching (RIE), plasma-enhanced CVD (PECVD) and plasma-enhanced atomic layer deposition (PEALD) are common process steps in the fabrication of semiconductor devices.

The plasma used in the semiconductor fabrication processes is commonly generated in a plasma chamber of a plasma processing system. A medium to high frequency radio frequency (RF) power source is coupled to the plasma chamber through an impedance matching network. A gas source supplies a process gas to the plasma chamber. The RF power source drives current through the gas in the plasma chamber. In response to the current through gas, the atoms of the gas break down into freely moving charged particles that form the plasma. The plasma can be used to perform various semiconductor fabrication processes such as deposition processes, etching processes and the like.

An impedance matching network is needed for efficiently delivering power from the RF power source to an antenna (coil, or circuit element) of the plasma chamber. More particularly, the impedance matching network is employed to eliminate the reflected power at the power source/antenna interface so that the maximum power output from the power source is delivered into the plasma chamber. In an embodiment, the antenna is a resonator antenna and the plasma processing system operates under resonant conditions. The RF power source is used to generate the plasma by exciting the resonator antenna at one of its resonant frequencies, such that the power factor at the resonator antenna is close to 1 (e.g., the phase angle between the voltage and current in the impedance matching network is matched to be 0°).

The impedance matching network that is used to deliver power from the RF power source to the resonator antenna of the plasma chamber comprises an adjustable shunt capacitor coupled between the output of the power source and ground, as well as a fixed value series inductor coupled between the output of the power source and the input of the resonator antenna.

As the plasma processes in the semiconductor industry further advance, there is a need to improve the existing impedance matching network for plasma processing systems that operate under resonant conditions. These improvements are needed to enhance the stability of these plasma processing systems under operation, and to provide an impedance matching network that is easier to implement with these plasma processing systems.

### SUMMARY

In accordance with an embodiment, a matching circuit for a plasma tool includes an impedance matching network configured to be coupled between a power supply and an antenna of a plasma chamber. The power supply is configured to provide power to and excite the antenna at a first frequency to generate a plasma. The impedance matching network is configured such that, during operation of the plasma chamber at the first frequency, a phase angle between a voltage and a current in the impedance matching network is matched to be 0°, and an impedance of the impedance matching network and the plasma chamber equals an impedance of the power supply. The impedance matching network includes a first adjustable reactive component; and a first fixed-length transmission line coupled between the first adjustable reactive component and an input of the antenna.

In accordance with an embodiment, a method includes providing power from a power supply to an antenna of a plasma chamber, an impedance matching network being coupled between an output of the power supply and an input of the antenna. The impedance matching network includes a first adjustable capacitor and a first fixed-length transmission line coupled between the first adjustable capacitor and the input of the antenna. The method further comprises configuring the plasma chamber to operate at a first frequency, where the first frequency is a resonant frequency of the antenna of the plasma chamber. The method further comprises based on the first frequency and a length of the first fixed-length transmission line, adjusting the impedance matching network such that an impedance of the impedance matching network and the plasma chamber equals an impedance of the power supply.

In accordance with an embodiment, a system comprises an antenna of a plasma chamber coupled to a power source; and an impedance matching network coupled between an output of the power source and an input of the antenna. The impedance matching network is configured such that, at a resonant frequency of the antenna, an impedance of the impedance matching network and the plasma chamber is equal to an impedance of the power source. The impedance matching network comprises a plurality of adjustable reactive components; and a first fixed-length transmission line coupled between the plurality of adjustable reactive components and the input of the antenna.

The foregoing has outlined rather broadly the features and technical advantages of the present disclosure in order that the detailed description of the disclosure that follows may be better understood. Additional features and advantages of the disclosure will be described herein, which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 illustrates a block diagram of a plasma processing system, in accordance with various embodiments of the present disclosure;

FIG. 2A illustrates a schematic of the plasma processing system shown in FIG. 1, in accordance with various embodiments of the present disclosure;

FIGS. 2B-2C illustrate a resonator antenna of the plasma processing system shown in FIG. 1, in accordance with various embodiments of the present disclosure;

FIG. 3 illustrates a first implementation of the impedance matching network shown in FIG. 1, in accordance with various embodiments of the present disclosure;

FIG. 4 illustrates a second implementation of the impedance matching network shown in FIG. 1, in accordance with various embodiments of the present disclosure;

FIG. 5 illustrates a third implementation of the impedance matching network shown in FIG. 1, in accordance with various embodiments of the present disclosure;

FIG. 6 illustrates a fourth implementation of the impedance matching network shown in FIG. 1, in accordance with various embodiments of the present disclosure;

FIG. 7 illustrates a fifth implementation of the impedance matching network shown in FIG. 1, in accordance with various embodiments of the present disclosure;

FIG. 8A illustrates a trace of reflected power versus frequency at which power is provided to a load by a power source, while the impedance matching network shown in FIG. 1 is in operation;

FIG. 8B illustrates example traces of impedance versus frequency at which power is provided to a load by a power source, while the impedance matching network shown in FIG. 1 is in operation;

FIG. 9 illustrates a flowchart diagram for a matching method that is used with the impedance matching network shown in FIG. 1, in accordance with various embodiments of the present disclosure;

Corresponding numerals and symbols in the different figures generally refer to corresponding parts unless otherwise indicated. The figures are drawn to clearly illustrate the relevant aspects of the various embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present disclosure provides many applicable inventive concepts that can be embodied in a wide variety of specific contexts. The specific embodiments discussed are merely illustrative of specific ways to make and use the disclosure, and do not limit the scope of the disclosure.

The present disclosure will be described with respect to preferred embodiments in a specific context, namely an apparatus and method for impedance matching between a medium frequency to high frequency radio frequency (RF) power source and a resonator antenna (also referred to subsequently as a resonator coil) of a plasma chamber. Impedance matching can be achieved while the RF power source is used to generate a plasma by exciting the resonator antenna at one of its resonant frequencies (e.g., under a resonant condition). The apparatus and method allows for a plasma process to be performed over a larger operating window, resulting in an improved plasma process that is also more stable. In addition, the apparatus and method for impedance matching is also easier to implement than existing impedance matching methodologies. Hereinafter, various embodiments will be explained in detail with reference to the accompanying drawings.

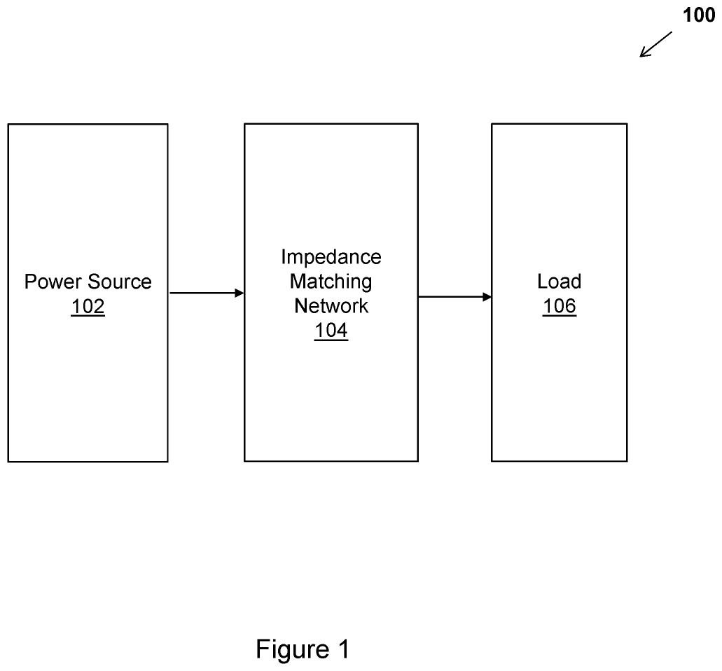

FIG. 1 illustrates a block diagram of a plasma processing system in accordance with various embodiments of the present disclosure. The plasma processing system 100 comprises a power source 102, an impedance matching network 104 and a load 106. As shown in FIG. 1, the output of the power source 102 is coupled to the input of the load 106 through the impedance matching network 104.

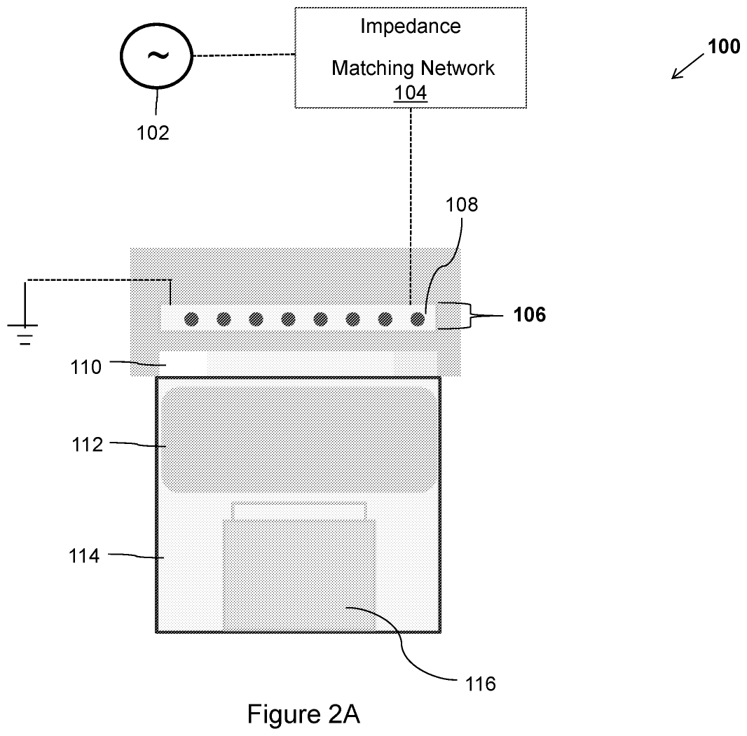

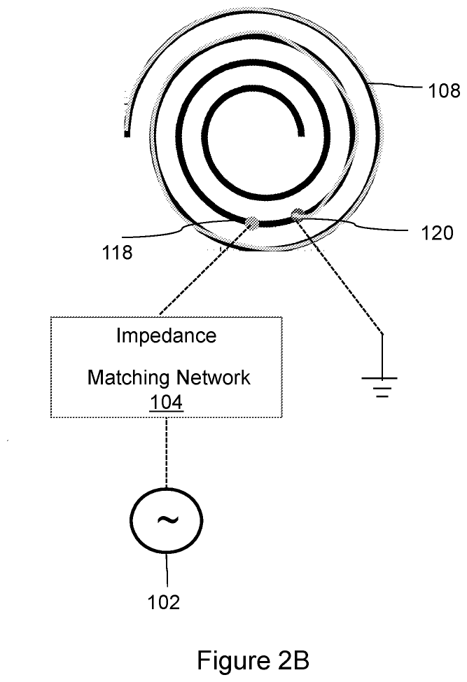

FIG. 2A shows a schematic of the plasma processing system 100. FIGS. 2B-2C shows a resonator antenna 108 of the plasma processing system 100 coupled to the power source 102 through the impedance matching network 104. In the plasma processing system 100, the load 106 is the resonator antenna 108 (also referred to subsequently as a resonator coil). The plasma processing system 100 may be used to generate plasma 112 to assist in a plasma process. The plasma process may be carried out in a plasma processing chamber 114 such as a medium frequency (MF) or high frequency (HF) plasma chamber. The impedance matching network 104 is employed to eliminate the reflected power at the power source 102/resonator antenna 108 interface so that the maximum power output from the power source 102 is delivered into the plasma processing chamber 114. The plasma process may include an etch process such as a Reactive Ion Etch (RIE) process, an Atomic Layer Etch (ALE) process or the like. In alternative embodiments, the plasma process may include a deposition process such as a Plasma-Enhanced Physical Vapor Deposition (PVD) process, a Plasma-Enhanced Chemical Vapor Deposition (CVD) process, an Atomic Layer Deposition (ALD) process or the like.

The power source 102 is employed to provide RF power to the load 106 (e.g., the resonator antenna 108). The resonator antenna 108 and the plasma processing system 100 operate under resonant conditions. The power source 102 is used to generate the plasma 112 in the plasma processing chamber 114 by exciting the resonator antenna 108 at one of its resonant frequencies, (e.g., a first resonant frequency) such that the power factor at the resonator antenna 108 is close to 1 (e.g., the phase angle between the voltage and current in the impedance matching network 104 is matched to be 0°, where matched to be 0° does not necessarily mean equal to 0° and can be within a range of +/−a few degrees from 0°). For example, matched to be 0° may be +/−5° around 0° in one embodiment, and +/−1°, +/−2°, or +/−10° while being centered around 0° in certain embodiments. The RF power may be used to sustain the plasma. The source impedance of the power source 102 may be predetermined (e.g., 50 ohm). In order to maximize RF power transmission to the load 106, and to prevent the RF power from being reflected back to the power source 102, the impedance matching network 104 is employed to match the load to the source impedance (e.g., 50 ohm) of power source 102 at the resonant frequency of the resonator antenna 108. Throughout the description, the power source 102 may be alternatively referred to as a power supply. The power source 102 may be employed to provide RF power to the load 106 as a continuous wave (CW). In an embodiment, the power source 102 may be employed to provide pulse-modulated RF power to the load 106. The power source 102 may provide pulse-modulated RF power to the load 106 at a modulation frequency that is in a range from 10 Hz to 100 MHz. In addition, the power source 102 may provide pulse-modulated RF power to the load 106 at a duty cycle that is in a range from 10 percent to 90 percent.

In an embodiment, the plasma processing chamber 114, may be a medium frequency (MF) or high frequency (HF) plasma chamber, or the like. The plasma processing chamber 114 may be a vacuum chamber. In some embodiments, the plasma processing chamber 114 is configured to operate plasma 112 at the first resonant frequency, wherein the first resonant frequency is in a range from about 1 MHz to about 27 MHz. For example, the plasma processing chamber 114 may be configured to operate plasma 112 at 1 MHz, 13.56 MHz, 27 MHz, or the like. The plasma processing chamber 114 may comprise any suitable elements such as a process gas input, a chuck 116 (e.g., to hold or support a substrate), or the like. A dielectric window 110 is disposed above the plasma processing chamber 114.

The resonator antenna 108 is disposed above the dielectric window 110. The dielectric window 110 may comprise quartz, or the like. The resonator antenna 108 serves as an RF antenna which transfers the RF power from the power source 102 across the dielectric window 110 into the plasma processing chamber 114 to generate and sustain the discharge. As shown in FIG. 2B, the resonator antenna 108 may comprise a planar coil which is designed to be a half-wave dipole antenna, the total length of the resonator antenna 108 being equal to a half-wavelength at the frequency of operation (e.g., the first resonant frequency). The power source 102 may be coupled to the resonator antenna 108 at a first point 118 on the resonator antenna 108. The first point 118 can be adjusted to provide optimum impedance matching between the power source 102 and the resonator antenna 108. In addition, the resonator antenna 108 may be connected to ground at a second point 120 on the resonator antenna 108. The length of the resonator antenna 108 from the second point 120 to either end of the resonator antenna 108 may be equal to a quarter-wavelength at the frequency of operation (e.g., the first resonant frequency). FIG. 2C shows that the resonator antenna 108 may be divided into an inner coil section 122 and an outer coil section 124 on either side of the first point 118. Both the inner coil section 122 and the outer coil section 124 receive RF power from the power source 102 at the first point 118. The combination of the inner coil section 122 and the outer coil section 124 serves as the load 106.

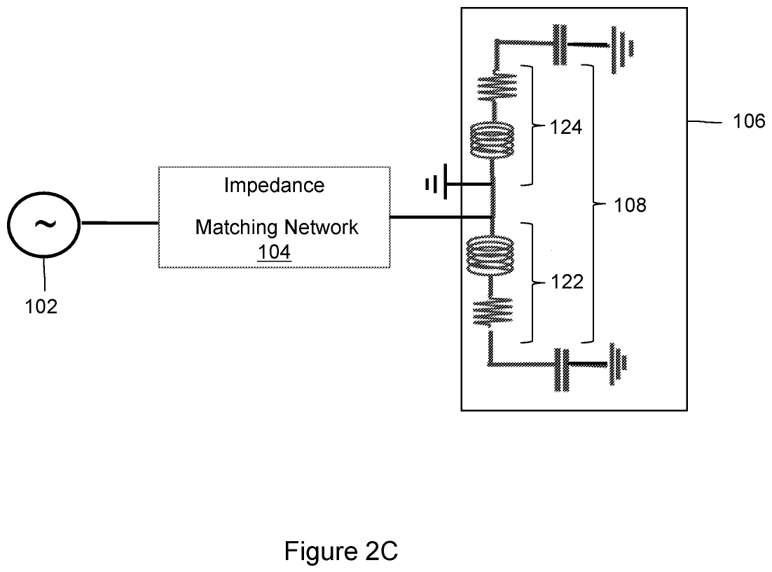

The impedance matching network 104 comprises at least one adjustable reactive component (e.g., a capacitor or an inductor) and at least one fixed-length transmission line. The transmission line is disposed between the load 106 (e.g., the resonator antenna 108) and the at least one adjustable reactive component. The transmission line may comprise a coaxial line that includes an inner conductor and an outer conductor around the inner conductor, with a dielectric insulator separating the inner conductor from the outer conductor. The transmission line has a fixed length to enable it to operate as a matching component of the impedance matching network 104. The fixed length of the transmission line allows it to operate as a reactive component (e.g., an inductive component) of the impedance matching network 104 with a fixed value. The fixed length is selected to achieve this fixed value, and so the fixed length of the transmission line is necessary for the impedance matching network 104 to achieve impedance matching. The transmission line can be used as a matching component of the impedance matching network 104 because the resonator antenna 108 and the plasma processing system 100 operate under resonant conditions. For example, the power source 102 is used to generate the plasma 112 in the plasma processing chamber 114 by exciting the resonator antenna 108 at one of its resonant frequencies (e.g., the first resonant frequency), such that the power factor at the resonator antenna 108 is close to 1 (e.g., the phase angle between the voltage and current in the impedance matching network 104 is matched to be 0°, where matched to be 0° does not necessarily mean equal to 0° and can be within a range of +/−a few degrees from 0°). If the resonator antenna 108 and the plasma processing system 100 were not operating under resonant conditions, the power factor at the resonator antenna 108 would not be close to 1. Using a fixed-length transmission line as a matching component in such a non-resonant system would lead to the generation of excessive amounts of heat in the impedance matching network that would be detrimental to the performance of the impedance matching network. The detailed structures of the impedance matching network 104 will be described below with respect to FIGS. 3-9.

FIG. 3 illustrates a first implementation of the impedance matching network 104 shown in FIGS. 1-2C in accordance with various embodiments of the present disclosure. The impedance matching network 104 comprises a first capacitor C1, a second capacitor C2, and a first transmission line T1. The first capacitor C1 is coupled between an output of the power source 102 and ground. The second capacitor C2 is coupled between a common node of the output of the power source 102 and the first capacitor C1, and the first transmission line T1. The first transmission line T1 is coupled between the second capacitor C2 and the input of the load 106. The first transmission line T1 is a fixed-length transmission line disposed between the load 106 and all the other matching components (e.g., the first capacitor C1 and the second capacitor C2) of the impedance matching network 104. In an embodiment, the first transmission line T1 has a fixed length equal to 2 feet.

In embodiments, the second capacitor C2 is an adjustable capacitor. For example, the second capacitor C2 may comprise a plurality of switch-capacitor networks connected in parallel. Each switch-capacitor network comprises a capacitor and a switch connected in series. By controlling the on and off of the switches of the plurality of switch-capacitor networks, the capacitance of the second capacitor C2 varies accordingly. Alternatively, the second capacitor C2 may have its capacitance changed by mechanical motion. For example, the distance and/or the overlapping area of the two plates of the second capacitor C2 may be adjustable through a suitable mechanical construction. In some embodiments, the second capacitor C2 is able to vary in a range from about 10 pF to about 1000 pF. In other embodiments, any other acceptable methods for changing the capacitance of the second capacitor C2 can be utilized.

It should be noted that while FIG. 3 illustrates the second capacitor C2 is implemented as a polarized capacitor as indicated by the symbol of the second capacitor C2, this is merely an example. Depending on different applications and design needs, the second capacitor C2 may be implemented as a non-polarized capacitor. Advantageous features may be achieved when the second capacitor C2 comprises a polarized capacitor. These may include allowing the second capacitor C2 to achieve a higher capacitance value than would be possible by using other types of capacitors. In some embodiments, the second capacitor C2 may be implemented as any suitable capacitors such as ceramic capacitors, film capacitors, electrolytic capacitors, polymer capacitors, any combinations thereof and the like.

The first capacitor C1 may be similar to the second capacitor C2, and hence the structure and the operating principles of the first capacitor C1, are not discussed in detail herein. The first capacitor C1 is implemented as an adjustable capacitor. The first capacitor C1 is able to vary in a range from about 10 pF to about 1000 pF.

Throughout the description, the first capacitor C1 may be alternatively referred to as a shunt capacitor, and the second capacitor C2 may be alternatively referred to as a series capacitor.

In operation, the load 106 (e.g., the resonator antenna 108) is configured to operate at the first resonant frequency, wherein the first resonant frequency is a frequency in a range from about 1 MHz to about 27 MHz. For example, the plasma processing chamber 114 may be configured to operate the plasma 112 at 1 MHz, 13.56 MHz, 27 MHz, or the like. The power source 102 is configured to provide power at the first resonant frequency for the load 106. The impedance matching network 104 is configured such that, at the first resonant frequency, the impedance of the impedance matching network 104 and the load 106 equals (e.g., is essentially or substantially equal to) an impedance of the power source 102. More particularly, the load 106 is configured to operate at the first resonant frequency. Based on this first resonant frequency, and the fixed-length first transmission line T1 disposed between the load 106 and all other matching components (e.g., the first capacitor C1 and the second capacitor C2) of the impedance matching network 104, the first capacitor C1 and the second capacitor C2 are adjusted individually or in combination such that the impedance of the impedance matching network 104 and the load 106 equals (e.g., is essentially or substantially equal to) the impedance of the power source 102.

Advantages can be achieved by having the impedance matching network 104 for the plasma processing system 100, the impedance matching network 104 comprising one or more adjustable reactive components (e.g., the first capacitor C1 and the second capacitor C2) and at least one fixed-length transmission line (e.g., the first transmission line T1) acting as a matching component of the impedance matching network 104. The first transmission line T1 is disposed between the load 106 (e.g., the resonator antenna 108) and the one or more adjustable reactive components of the impedance matching network 104. For example, the first capacitor C1 may be a shunt capacitor, the second capacitor C2 may be a series capacitor, and the first transmission line T1 may be coupled between the input of the load 106 and the second capacitor C2. One advantage is that when the plasma processing system 100 is operating under resonant conditions, this apparatus and method for impedance matching of the plasma processing system 100 is easier and simpler to implement than existing impedance matching methods. A second advantage is that during impedance matching of the plasma processing system 100, only a gradual and close to symmetrical increase and decrease in reflected power is seen close to a resonant frequency of the load 106. As a result of this gradual and close to symmetrical increase and decrease in reflected power, a wider window of operation is available for tuning and for operating the plasma processing system 100, and this leads to an improved plasma process that is also more stable.

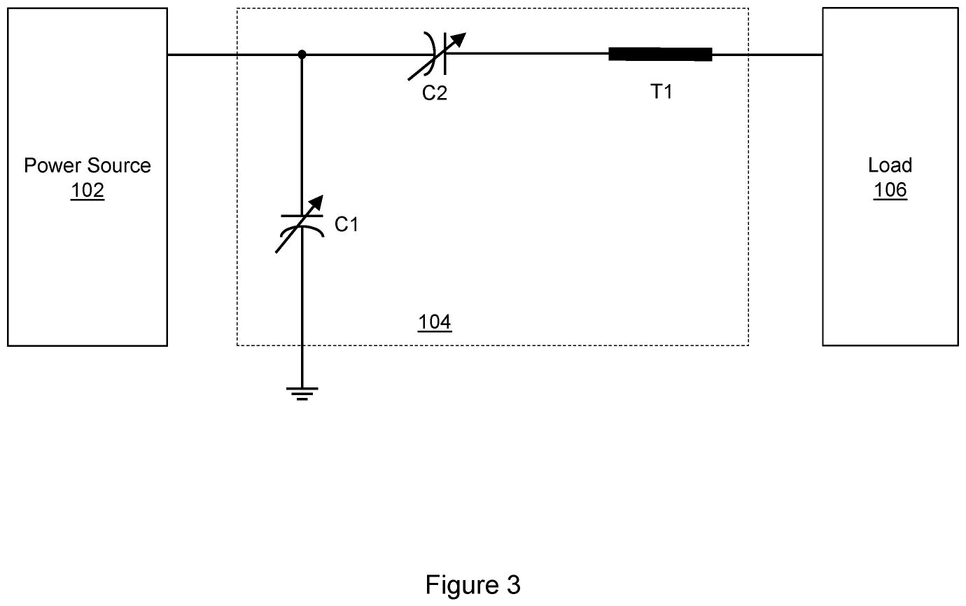

FIG. 4 illustrates a second implementation of the impedance matching network 104 shown in FIGS. 1-2C in accordance with various embodiments of the present disclosure. The second implementation of the impedance matching network 104 shown in FIG. 4 is similar to the first implementation shown in FIG. 3 except that the impedance matching network 104 does not comprise the first capacitor C1 coupled between an output of the power source 102 and ground. The second capacitor C2 and the first transmission line T1 are coupled in series between the output of the power source 102 and the input of the load 106. The first transmission line T1 is coupled between the input of the load 106 and the second capacitor C2. The first transmission line T1 is a fixed-length transmission line disposed between the load 106 and all the other matching components (e.g., the second capacitor C2) of the impedance matching network 104.

In operation, the load 106 (e.g., the resonator antenna 108) is configured to operate at the first resonant frequency. The power source 102 is configured to provide power at the first resonant frequency for the load 106. The impedance matching network 104 is configured such that, at the first resonant frequency, the impedance of the impedance matching network 104 and the load 106 equals (e.g., is essentially or substantially equal to) an impedance of the power source 102. More particularly, the load 106 is configured to operate at the first resonant frequency. Based on this first resonant frequency, and the fixed-length first transmission line T1 disposed between the load 106 and all other matching components (e.g., the second capacitor C2) of the impedance matching network 104, the second capacitor C2 is adjusted such that the impedance of the impedance matching network 104 and the load 106 equals (e.g., is essentially or substantially equal to) the impedance of the power source 102. In an embodiment, the second capacitor C2 of the impedance matching network 104 may also be replaced with an adjustable inductor, the adjustable inductor being in series with the first transmission line T1.

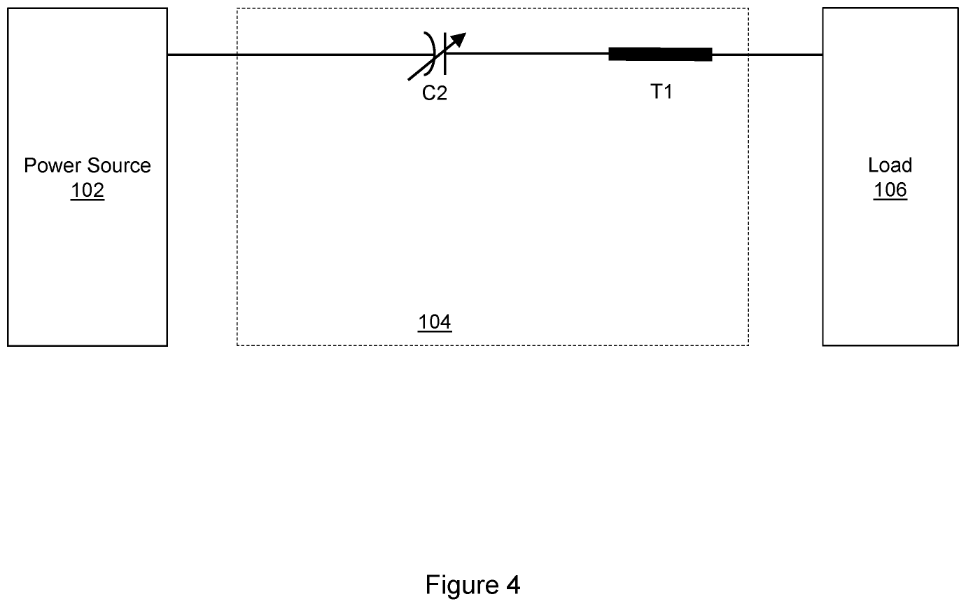

FIG. 5 illustrates a third implementation of the impedance matching network 104 shown in FIGS. 1-2C in accordance with various embodiments of the present disclosure. The third implementation of the impedance matching network 104 shown in FIG. 5 is similar to the first implementation shown in FIG. 3 except that the impedance matching network 104 also comprises a first inductor L1 and a second inductor L2. The first inductor L1 is coupled between a common node of the second capacitor C2 and the second inductor L2, and ground. The second inductor L2 is coupled between a common node of the first inductor L1 and the second capacitor C2, and the first transmission line T1. The first transmission line T1 is coupled between the input of the load 106 and the second inductor L2. The first transmission line T1 is a fixed-length transmission line disposed between the load 106 and all the other matching components (e.g., the first capacitor C1, the second capacitor C2, the first inductor L1, and the second inductor L2) of the impedance matching network 104.

In an embodiment, the first inductor L1 is an adjustable inductor. The first inductor L1 may comprise a plurality of switch-inductor networks connected in parallel or in series.

The second inductor L2 may be similar to the first inductor L1, and hence the structure and the operating principles of the second inductor L2 are not discussed in detail herein. The second inductor L2 is an adjustable inductor. The second inductor L2 is able to vary in a range from about 1 μH to about 1000 μH.

In operation, the load 106 (e.g., the resonator antenna 108) is configured to operate at the first resonant frequency. The power source 102 is configured to provide power at the first resonant frequency for the load 106. The impedance matching network 104 is configured such that, at the first resonant frequency, the impedance of the impedance matching network 104 and the load 106 equals (e.g., is essentially or substantially equal to) an impedance of the power source 102. More particularly, the load 106 is configured to operate at the first resonant frequency. Based on this first resonant frequency, and the fixed-length first transmission line T1 disposed between the load 106 and all other matching components (e.g., the first capacitor C1, the second capacitor C2, the first inductor L1, and the second inductor L2) of the impedance matching network 104, the first capacitor C1, the second capacitor C2, the first inductor L1, and the second inductor L2 are adjusted individually or in combination such that the impedance of the impedance matching network 104 and the load 106 equals (e.g., is essentially or substantially equal to) the impedance of the power source 102.

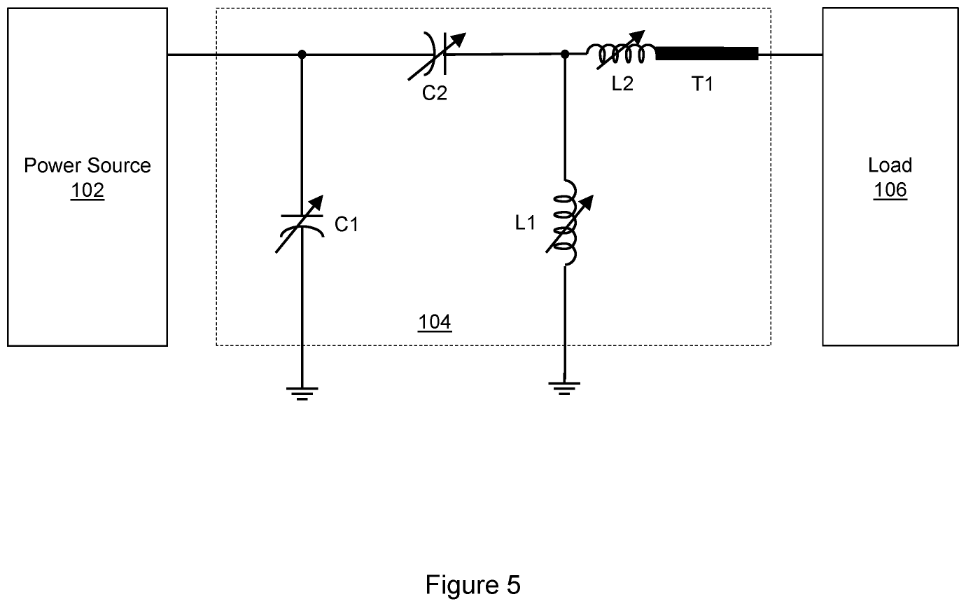

FIG. 6 illustrates a fourth implementation of the impedance matching network 104 shown in FIGS. 1-2C in accordance with various embodiments of the present disclosure. The fourth implementation of the impedance matching network 104 shown in FIG. 6 is similar to the second implementation shown in FIG. 4 except that the impedance matching network 104 also comprises a second transmission line T2 and switches S1 and S2. The second transmission line T2 is a fixed-length transmission line similar in structure to the first transmission line T1. The second transmission line may have a fixed length equal to 3 feet. In an embodiment, the first transmission line T1 and the second transmission line T2 have different lengths. The first transmission line T1 is a fixed-length transmission line disposed between the load 106 and other matching components (e.g., the switch S1 and the second capacitor C2) of the impedance matching network 104. The second transmission line T2 is a fixed-length transmission line disposed between the load 106 and other matching components (e.g., the switch S2 and the second capacitor C2) of the impedance matching network 104.

As shown in FIG. 6, the switch S1 and the switch S2 function as path selectors. More particularly, the switch S1 is configured such that the first transmission line T1 functions as a selectable element of the impedance matching network 104 by controlling the switch S1, and the switch S2 is configured such that the second transmission line T2 functions as a selectable element of the impedance matching network 104 by controlling the switch S2. The first transmission line T1 and the switch S1 are coupled in series between a common node of the second capacitor C2 and the switch S2, and the input of the load 106. The second transmission line T2 and the switch S2 are coupled in series between a common node of the second capacitor C2 and the switch S1, and the input of the load 106. The switch S1 and the switch S2 may be implemented as any suitable switches such as mechanical switches, solid state switches, any combinations thereof and the like. Although FIG. 6 shows two fixed-length transmission lines (e.g., the first transmission line T1 and the second transmission line T2) and two switches (e.g., the switch S1 and the switch S2), any number of fixed-length transmission lines and switches may be included in the impedance matching network 104.

The switch S1 and the switch S2 are employed to provide control variables for providing impedance matching. In particular, by controlling the on and off of the switch S1, the first transmission line T1 becomes a selectable element of the impedance matching, and by controlling the on and off of the switch S2, the second transmission line T2 becomes a selectable element of the impedance matching. For the impedance matching network 104 to function, at least one of the switch S1 or switch S2 must be placed in an on position to include the first transmission line T1 or the second transmission line T2 in the impedance matching network 104.

In operation, the load 106 (e.g., the resonator antenna 108) is configured to operate at the first resonant frequency. The power source 102 is configured to provide power at the first resonant frequency for the load 106. The impedance matching network 104 is configured such that, at the first resonant frequency, the impedance of the impedance matching network 104 and the load 106 equals (e.g., is essentially or substantially equal to) an impedance of the power source 102. More particularly, the load 106 is configured to operate at the first resonant frequency. Based on this first resonant frequency, one or both of the switch S1 and the switch S2 are placed in the on position, to include one or both of the first transmission line T1 and the second transmission line T2 in the impedance matching network 104, respectively. The second capacitor C2 is then adjusted based on which of the switches S1 and S2 are in the on position, such that the impedance of the impedance matching network 104 and the load 106 equals (e.g., is essentially or substantially equal to) the impedance of the power source 102. In an embodiment, the second capacitor C2 of the impedance matching network 104 may also be replaced with an adjustable inductor.

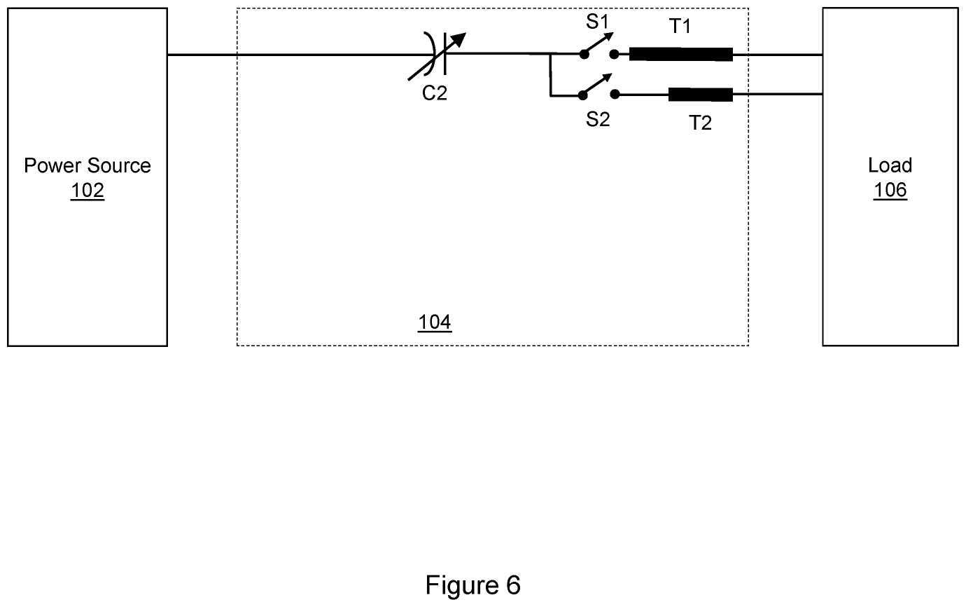

FIG. 7 illustrates a fifth implementation of the impedance matching network 104 shown in FIGS. 1-2C in accordance with various embodiments of the present disclosure. The fifth implementation of the impedance matching network 104 shown in FIG. 7 is similar to the fourth implementation shown in FIG. 6 except that the impedance matching network 104 also comprises the first capacitor C1. The first capacitor C1 is coupled between an output of the power source 102 and ground. The first transmission line T1 is a fixed-length transmission line disposed between the load 106 and other matching components (e.g., the switch S1, the first capacitor C1, and the second capacitor C2) of the impedance matching network 104. The second transmission line T2 is a fixed-length transmission line disposed between the load 106 and other matching components (e.g., the switch S2, the first capacitor C1, and the second capacitor C2) of the impedance matching network 104.

In operation, the load 106 (e.g., the resonator antenna 108) is configured to operate at the first resonant frequency. The power source 102 is configured to provide power at the first resonant frequency for the load 106. The impedance matching network 104 is configured such that, at the first resonant frequency, the impedance of the impedance matching network 104 and the load 106 equals (e.g., is essentially or substantially equal to) an impedance of the power source 102. More particularly, the load 106 is configured to operate at the first resonant frequency. Based on this first resonant frequency, one or both of the switch S1 and the switch S2 are placed in the on position, to include one or both of the first transmission line T1 and the second transmission line T2 in the impedance matching network 104, respectively. The first capacitor C1 and the second capacitor C2 are then adjusted based on which of the switches S1 and S2 are in the on position, such that the impedance of the impedance matching network 104 and the load 106 equals (e.g., is essentially or substantially equal to) the impedance of the power source 102.

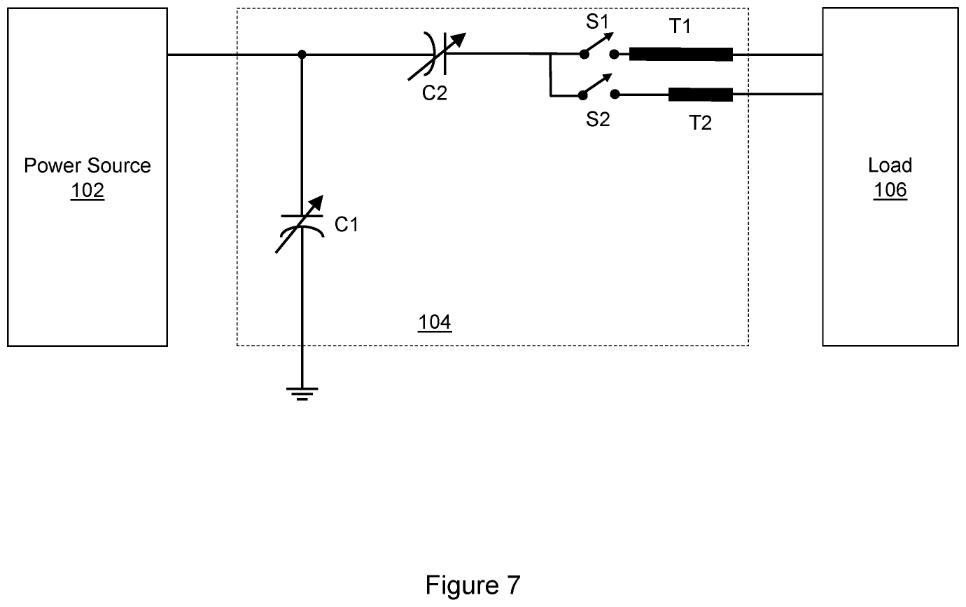

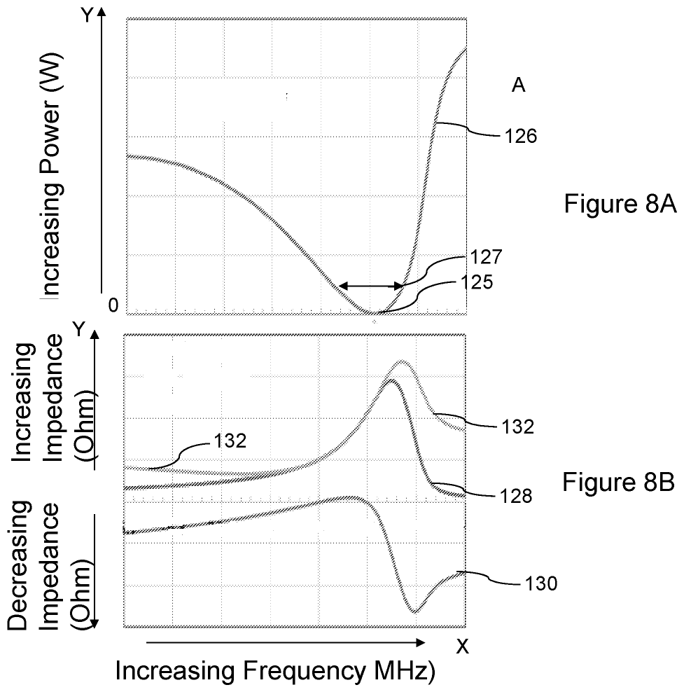

FIG. 8A shows an example trace 126 of reflected power versus frequency at which power is provided to the load 106 by the power source 102, while the impedance matching network 104 is in operation. FIG. 8A indicates that close to either side of a point 125 that corresponds to the lowest reflected power (e.g., at the first resonant frequency), there is no sharp or abrupt increase in reflected power. Rather, the trace 126 indicates that during impedance matching, only a gradual and close to symmetrical increase and decrease in reflected power is seen close to either side of the point 125. As a result of this gradual and close to symmetrical increase and decrease in reflected power, a wider window of operation 127 is available for tuning and for operating the plasma processing system 100, and this leads to an improved plasma process that is also more stable. FIG. 8B shows example traces of impedance vs frequency at which power is provided to the load 106 by the power source 102, while the impedance matching network 104 is in operation. FIGS. 8A and 8B use the same frequency scale on the x-axis. An example trace 128 shows the real impedance's dependence on the frequency at which power is provided to the load 106, while the impedance matching network 104 is in operation. An example trace 130 shows the imaginary impedance's dependence on the frequency at which power is provided to the load 106, while the impedance matching network 104 is in operation. An example trace 132 shows the total impedance's dependence on the frequency at which power is provided to the load 106, while the impedance matching network 104 is in operation.

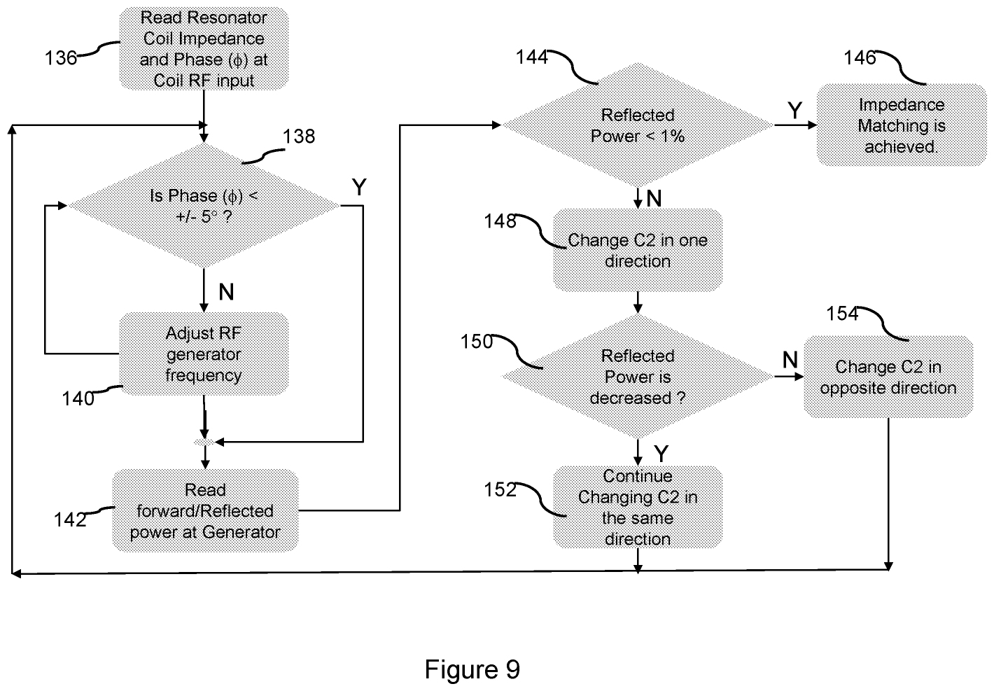

FIG. 9 illustrates a flowchart diagram that shows a matching method that is used with the impedance matching network 104 to ensure that the impedance of the impedance matching network 104 and the load 106 equals (e.g., is essentially or substantially equal to) the impedance of the power source 102. The matching method is designed to be used with the second implementation of the impedance matching network 104 described previously in FIG. 4. The matching method may be in the form of an algorithm that is run using a program stored in a memory of an associated controller that is coupled to the impedance matching network 104. Starting in flowchart block 136 of FIG. 9, the impedance of the impedance matching network 104, and the phase angle between the voltage and current in the impedance matching network 104 are measured in real-time at a point between the first transmission line T1 and the load 106 (e.g., the resonator antenna 108). These can be measured using any suitable means, such as current-voltage sensors, impedance meters, or the like.

As shown in flowchart block 138 of FIG. 9, the measured phase angle between the voltage and current in the impedance matching network 104 is then compared to a preset threshold. This preset threshold may be +/−5° in one embodiment, and +/−1°, +/−2°, or +/−10° in certain embodiments. If the measured phase angle between the voltage and current in the impedance matching network 104 is greater than the preset threshold (e.g., +/−5°), the frequency of the power source 102 is adjusted as shown in flowchart block 140, so as to move it closer to the first resonant frequency for the load 106. The adjusted frequency now has an adjusted phase angle between the voltage and current in the impedance matching network 104. This adjusted phase angle between the voltage and current in the impedance matching network 104 is compared to the preset threshold (e.g., +/−5°) once again, and the process of adjusting the frequency of the power source 102 to move it closer to the first resonant frequency for the load 106 is repeated cyclically as long as the adjusted phase angle is greater than the preset threshold (e.g., +/−5°).

Once the measured phase angle between the voltage and current in the impedance matching network is smaller than the preset threshold (e.g., +/−5°), the forward power and the reflected power at the power source 102 are measured in real-time as shown in flowchart block 142. As shown in flowchart block 144 of FIG. 9, the measured reflected power at the power source 102 is then compared to a preset threshold (e.g., 1 percent of the measured forward power). If the measured reflected power at the power source 102 is smaller than the preset threshold (e.g., 1 percent of the measured forward power), impedance matching is achieved (as shown in flowchart block 146) and the plasma processing system 100 is said to be operating under resonant conditions, with the frequency of the power source 102 being a resonant frequency (e.g., the first resonant frequency) for the load 106.

If the measured reflected power at the power source 102 is equal to or greater than the preset threshold (e.g., 1 percent of the measured forward power), the second capacitor C2 is adjusted in a first direction as shown in flowchart block 148 to either increase or decrease the capacitance value of the second capacitor C2. This adjustment of the second capacitor C2 results in an adjusted reflected power that is measured at the power source 102. As shown in flowchart block 150, this adjusted reflected power is compared to the previously measured reflected power obtained during the step shown in flowchart block 142. If the adjusted reflected power is smaller than the previously measured reflected power, the second capacitor C2 is further adjusted in the first direction as shown in flowchart block 152 to either increase or decrease the capacitance value of the second capacitor C2. However, if the adjusted reflected power is not smaller than the previously measured reflected power, the second capacitor C2 is adjusted in a second direction as shown in flowchart block 154 to either increase or decrease the capacitance value of the second capacitor C2. The second direction is opposite to the first direction.

After either of the steps described in flowchart block 152 or flowchart block 154 are performed, the step shown in flowchart block 138 and the subsequent steps of the flowchart diagram in FIG. 9 that were described above are performed again in a cyclical fashion until impedance matching is achieved (as shown in flowchart block 146). When impedance matching is achieved, the plasma processing system 100 is said to be operating under resonant conditions, with the frequency of the power source 102 being a resonant frequency (e.g., the first resonant frequency) for the load 106.

Although embodiments of the present disclosure and its advantages have been described in detail, it should be understood that various changes, substitutions and alterations can be made herein without departing from the spirit and scope of the disclosure as defined by the appended claims.

Example embodiments of the invention are described below. Other embodiments can also be understood from the entirety of the specification as well as the claims filed herein.

Example 1. An embodiment matching circuit for a plasma tool includes an impedance matching network configured to be coupled between a power supply and an antenna of a plasma chamber. The power supply is configured to provide power to and excite the antenna at a first frequency to generate a plasma. The impedance matching network is configured such that, during operation of the plasma chamber at the first frequency, a phase angle between a voltage and a current in the impedance matching network is matched to be 0°, and an impedance of the impedance matching network and the plasma chamber equals an impedance of the power supply. The impedance matching network includes a first adjustable reactive component; and a first fixed-length transmission line coupled between the first adjustable reactive component and an input of the antenna.

Example 2. The matching circuit of example 1, where the first frequency is a resonant frequency of the antenna.

Example 3. The matching circuit of example 1 or 2, where the first adjustable reactive component is a capacitor or an inductor.

Example 4. The matching circuit of any one of examples 1-3, further including a first adjustable capacitor coupled between an output of the power supply and ground, the first adjustable reactive component being a second adjustable capacitor coupled between a common node of the output of the power supply and the first adjustable capacitor, and the first fixed-length transmission line.

Example 5. The matching circuit of example 4, where the impedance matching network further includes: a second fixed-length transmission line coupled to the input of the antenna; a first switch connected in series to the first fixed-length transmission line, where the first switch is configured such that the first fixed-length transmission line functions as a selectable element of the impedance matching network by controlling the first switch; and a second switch connected in series to the second fixed-length transmission line, where the second switch is configured such that the second fixed-length transmission line functions as a selectable element of the impedance matching network by controlling the second switch.

Example 6. The matching circuit of example 5, where a length of the first fixed-length transmission line is different from a length of the second fixed-length transmission line.

Example 7. The matching circuit of any one of examples 1-6, wherein the impedance matching network further includes: a third fixed-length transmission line coupled to the input of the antenna; a third switch connected in series to the first fixed-length transmission line, where the third switch is configured such that the first fixed-length transmission line functions as a selectable element of the impedance matching network by controlling the third switch; and a fourth switch connected in series to the third fixed-length transmission line, where the fourth switch is configured such that the third fixed-length transmission line functions as a selectable element of the impedance matching network by controlling the fourth switch.

Example 8. The matching circuit of example 7, where a length of the first fixed-length transmission line is different from a length of the third fixed-length transmission line.

Example 9. A method includes providing power from a power supply to an antenna of a plasma chamber, an impedance matching network being coupled between an output of the power supply and an input of the antenna. The impedance matching network includes a first adjustable capacitor and a first fixed-length transmission line coupled between the first adjustable capacitor and the input of the antenna. The method further comprises configuring the plasma chamber to operate at a first frequency, where the first frequency is a resonant frequency of the antenna of the plasma chamber. The method further comprises based on the first frequency and a length of the first fixed-length transmission line, adjusting the impedance matching network such that an impedance of the impedance matching network and the plasma chamber equals an impedance of the power supply.

Example 10. The method of example 9, where configuring the plasma chamber to operate at the first frequency includes: measuring a phase angle between a voltage and a current in the impedance matching network at a point between the first fixed-length transmission line and the antenna; and adjusting a frequency of the power supplied by the power supply when the phase angle is greater than a first preset threshold.

Example 11. The method of example 10, where the first preset threshold is +/−5°.

Example 12. The method of any one of examples 9-11, where adjusting the impedance matching network includes: measuring forward power and reflected power at the power supply; and adjusting the first adjustable capacitor when the reflected power is equal to or greater than a second preset threshold, the second preset threshold being 1 percent of the forward power.

Example 13. The method of any one of examples 9-12, where the impedance matching network further includes a second adjustable capacitor coupled between the output of the power supply and ground, the first adjustable capacitor being coupled between a common node of the output of the power supply and the second adjustable capacitor, and the first fixed-length transmission line.

Example 14. The method of any one of examples 9-13, where the impedance matching network further includes: a second fixed-length transmission line coupled to the input of the antenna; a first switch connected in series to the first fixed-length transmission line, where the first switch is configured such that the first fixed-length transmission line functions as a selectable element of the impedance matching network by controlling the first switch; and a second switch connected in series to the second fixed-length transmission line, where the second switch is configured such that the second fixed-length transmission line functions as a selectable element of the impedance matching network by controlling the second switch.

Example 15. The method of example 14, where a length of the first fixed-length transmission line is different from a length of the second fixed-length transmission line.

Example 16. A system comprises an antenna of a plasma chamber coupled to a power source; and an impedance matching network coupled between an output of the power source and an input of the antenna. The impedance matching network is configured such that, at a resonant frequency of the antenna, an impedance of the impedance matching network and the plasma chamber is equal to an impedance of the power source. The impedance matching network comprises a plurality of adjustable reactive components; and a first fixed-length transmission line coupled between the plurality of adjustable reactive components and the input of the antenna.

Example 17. The system of example 16, where the plurality of adjustable reactive components include: a first adjustable capacitor coupled between the output of the power source and ground; and a second adjustable capacitor coupled between a common node of the output of the power source and the first adjustable capacitor, and the first fixed-length transmission line, the first fixed-length transmission line being coupled between the second adjustable capacitor and the input of the antenna.

Example 18. The system of example 16 or 17, where the impedance matching network further includes: a second fixed-length transmission line coupled to the input of the antenna; a first switch connected in series to the first fixed-length transmission line, where the first switch is configured such that the first fixed-length transmission line functions as a selectable element of the impedance matching network by controlling the first switch; and a second switch connected in series to the second fixed-length transmission line, where the second switch is configured such that the second fixed-length transmission line functions as a selectable element of the impedance matching network by controlling the second switch.

Example 19. The system of example 18, where the plurality of adjustable reactive components include: a first adjustable capacitor coupled between the output of the power source and ground; and a second adjustable capacitor coupled between a common node of the output of the power source and the first adjustable capacitor, and a common node of the first switch and the second switch.

Example 20. The system of any one of examples 16-19, where the plurality of adjustable reactive components include: a first adjustable capacitor coupled between the output of the power source and ground; a second adjustable capacitor coupled between a common node of the output of the power source and the first adjustable capacitor, and a common node of a first adjustable inductor and a second adjustable inductor; the first adjustable inductor coupled between a common node of the second adjustable capacitor and the second adjustable inductor, and ground; and the second adjustable inductor coupled between a common node of the first adjustable inductor and the second adjustable capacitor, and the first fixed-length transmission line.

Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A matching circuit for a plasma tool comprising:
an impedance matching network configured to be coupled between a power supply and an antenna of a plasma chamber, the power supply being configured to provide power to and excite the antenna at a first frequency to generate a plasma, the impedance matching network being configured such that, during operation of the plasma chamber at the first frequency, a phase angle between a voltage and a current in the impedance matching network is matched to be 0°, and an impedance of the impedance matching network and the plasma chamber equals an impedance of the power supply, the impedance matching network comprising:
a first adjustable reactive component; and
a first fixed-length transmission line coupled between the first adjustable reactive component and an input of the antenna.

2. The matching circuit of claim 1, wherein the first frequency is a resonant frequency of the antenna.

3. The matching circuit of claim 1, wherein the first adjustable reactive component is a capacitor or an inductor.

4. The matching circuit of claim 1, further comprising a first adjustable capacitor coupled between an output of the power supply and ground, the first adjustable reactive component being a second adjustable capacitor coupled between a common node of the output of the power supply and the first adjustable capacitor, and the first fixed-length transmission line.

5. The matching circuit of claim 4, wherein the impedance matching network further comprises:
a second fixed-length transmission line coupled to the input of the antenna;
a first switch connected in series to the first fixed-length transmission line, wherein the first switch is configured such that the first fixed-length transmission line functions as a selectable element of the impedance matching network by controlling the first switch; and
a second switch connected in series to the second fixed-length transmission line, wherein the second switch is configured such that the second fixed-length transmission line functions as a selectable element of the impedance matching network by controlling the second switch.

6. The matching circuit of claim 5, wherein a length of the first fixed-length transmission line is different from a length of the second fixed-length transmission line.

7. The matching circuit of claim 1, wherein the impedance matching network further comprises:
a third fixed-length transmission line coupled to the input of the antenna;
a third switch connected in series to the first fixed-length transmission line, wherein the third switch is configured such that the first fixed-length transmission line functions as a selectable element of the impedance matching network by controlling the third switch; and
a fourth switch connected in series to the third fixed-length transmission line, wherein the fourth switch is configured such that the third fixed-length transmission line functions as a selectable element of the impedance matching network by controlling the fourth switch.

8. The matching circuit of claim 7, wherein a length of the first fixed-length transmission line is different from a length of the third fixed-length transmission line.

9. A method comprising:
providing power from a power supply to an antenna of a plasma chamber, an impedance matching network being coupled between an output of the power supply and an input of the antenna, the impedance matching network comprising a first adjustable capacitor and a first fixed-length transmission line coupled between the first adjustable capacitor and the input of the antenna;
configuring the plasma chamber to operate at a first frequency, the first frequency being a resonant frequency of the antenna of the plasma chamber; and
based on the first frequency and a length of the first fixed-length transmission line, adjusting the impedance matching network such that an impedance of the impedance matching network and the plasma chamber equals an impedance of the power supply.

10. The method of claim 9, wherein configuring the plasma chamber to operate at the first frequency comprises:
measuring a phase angle between a voltage and a current in the impedance matching network at a point between the first fixed-length transmission line and the antenna; and
adjusting a frequency of the power supplied by the power supply when the phase angle is greater than a first preset threshold.

11. The method of claim 10, wherein the first preset threshold is +/−5°.

12. The method of claim 9, wherein adjusting the impedance matching network comprises:
measuring forward power and reflected power at the power supply; and
adjusting the first adjustable capacitor when the reflected power is equal to or greater than a second preset threshold, the second preset threshold being 1 percent of the forward power.

13. The method of claim 9, wherein the impedance matching network further comprises a second adjustable capacitor coupled between the output of the power supply and ground, the first adjustable capacitor being coupled between a common node of the output of the power supply and the second adjustable capacitor, and the first fixed-length transmission line.

14. The method of claim 9, wherein the impedance matching network further comprises:
a second fixed-length transmission line coupled to the input of the antenna;
a first switch connected in series to the first fixed-length transmission line, wherein the first switch is configured such that the first fixed-length transmission line functions as a selectable element of the impedance matching network by controlling the first switch; and
a second switch connected in series to the second fixed-length transmission line, wherein the second switch is configured such that the second fixed-length transmission line functions as a selectable element of the impedance matching network by controlling the second switch.

15. The method of claim 14, wherein a length of the first fixed-length transmission line is different from a length of the second fixed-length transmission line.

16. A system comprising:
an antenna of a plasma chamber coupled to a power source; and
an impedance matching network coupled between an output of the power source and an input of the antenna, wherein the impedance matching network is configured such that, at a resonant frequency of the antenna, an impedance of the impedance matching network and the plasma chamber is equal to an impedance of the power source, wherein the impedance matching network comprises:
a plurality of adjustable reactive components; and
a first fixed-length transmission line coupled between the plurality of adjustable reactive components and the input of the antenna.

17. The system of claim 16, wherein the plurality of adjustable reactive components comprise:
a first adjustable capacitor coupled between the output of the power source and ground; and
a second adjustable capacitor coupled between a common node of the output of the power source and the first adjustable capacitor, and the first fixed-length transmission line, the first fixed-length transmission line being coupled between the second adjustable capacitor and the input of the antenna.

18. The system of claim 16, wherein the impedance matching network further comprises:
a second fixed-length transmission line coupled to the input of the antenna;
a first switch connected in series to the first fixed-length transmission line, wherein the first switch is configured such that the first fixed-length transmission line functions as a selectable element of the impedance matching network by controlling the first switch; and
a second switch connected in series to the second fixed-length transmission line, wherein the second switch is configured such that the second fixed-length transmission line functions as a selectable element of the impedance matching network by controlling the second switch.

19. The system of claim 18, wherein the plurality of adjustable reactive components comprise:
a first adjustable capacitor coupled between the output of the power source and ground; and
a second adjustable capacitor coupled between a common node of the output of the power source and the first adjustable capacitor, and a common node of the first switch and the second switch.

20. The system of claim 16, wherein the plurality of adjustable reactive components comprise:
a first adjustable capacitor coupled between the output of the power source and ground;
a second adjustable capacitor coupled between a common node of the output of the power source and the first adjustable capacitor, and a common node of a first adjustable inductor and a second adjustable inductor;
the first adjustable inductor coupled between a common node of the second adjustable capacitor and the second adjustable inductor, and ground; and
the second adjustable inductor coupled between a common node of the first adjustable inductor and the second adjustable capacitor, and the first fixed-length transmission line.
